(19) United States
(12) Patent Application Publication
(10) Pub. No.: US 2020/0216943 A1
(43) Pub. Date: Jul. 9, 2020

(54) FABRICATION PROCESS OF 3D-STRUCTURED SURFACE-ENHANCED RAMAN SPECTROSCOPY (SERS) SUBSTRATES BY USING A LASER MARKING MACHINE TO CREATE ROUGHNESS ON METAL SHEETS

(71) Applicant: NATIONAL SCIENCE AND TECHNOLOGY DEVELOPMENT AGENCY, Pathumthani (TH)

(72) Inventors: Pitak EIAMCHAI, Pathumthani (TH); Noppadon NUNTAWONG, Pathumthani (TH); Mati HORPRATHUM, Pathumthani (TH); Saksorn LIMWICHEAN, Pathumthani (TH); Nutthamon LIMSUWAN, Pathumthani (TH); Viyapol PATTHANASETTAKUL, Pathumthani (TH); Chanunthorn CHANANONNAWATHORN, Pathumthani (TH)

(73) Assignee: NATIONAL SCIENCE AND TECHNOLOGY DEVELOPMENT AGENCY, Pathumthani (TH)

(21) Appl. No.: 16/648,309

(22) PCT Filed: Aug. 31, 2018
(86) PCT No.: PCT/TH2018/000037

§ 371 Date: Mar. 18, 2020

(30) Foreign Application Priority Data
Sep. 22, 2017 (TH) 1701005533

(51) Int. Cl. C23C 14/02; C23C 14/16; C23C 14/35; B32B 15/16

(52) U.S. Cl. CPC C23C 14/028; C23C 14/16; G01N 21/658; B32B 15/16; C23C 14/35

(57) ABSTRACT

The present invention provides a process of making 3D-structured SERS substrates by using a laser marking machine as part of the fabrication procedures. The 3D-structured SERS substrates in the present invention comprises of a roughened metal sheet on which noble metal nanoparticles are coated. Rough structures on the metal sheet are created by a laser marking machine. Noble metal nanoparticles are deposited onto the substrates in a magnetron sputtering system. The specific parameters involved in the settings of a laser marking machine include a laser power in a range of 1-20 W, fill spacing of 0.02-0.15 mm, speed of 1-10,000 mm/s, frequency of 20-200 kHz and repetition rate of 1-50 times. The 3D-structured SERS substrates in the present invention are able to give high enhancement of Raman signals and can detect methylene blue solution with concentration as low as 1×1O″6 M.

### FIELD OF THE INVENTION

The present invention relates to laser engraving technique on metal sheets, metal coating by sputtering techniques, thin film technology, as well as, Raman spectroscopy, and material science.

### BACKGROUND OF THE INVENTION

Surface-enhanced Raman Spectroscopy (SERS) is a technique that has been developed to amplify Raman scattering, allowing for low-concentration detection of bio-molecules and bio-chemical analytes. Noble metals such as copper, gold, silver, palladium and platinum, contain high volume of free electrons. When the surface of these noble metals has a roughness in a nanometer range, they can enhance Raman signals significantly. This discovery became known in 1973 by Fleishmann et al, who demonstrated that roughened silver sheets could magnify the Raman signals by 6 times. (Fleischmann, M., Hendra, P. J., McQuillan, A. M. Chem. Phys. Lett. 1974, 26, 123; Weaver, M. J., Farquharson, S., Tadayyoni, M. A. J. Chem Phys. 1985, 82, 4867) As a set up of SERS measurements, an analyte one wants to identify can be dropped onto the roughened surface of a noble metal. The enhancement of Raman signals occurs when photons in injecting laser light cause the stimulations of the noble metal's free electrons that are clouding on the surface of the analyte in question. These stimulations yield surface plasmons that in turn give out light scattering energy. (Weaver, M. J., Farquharson, S., Tadayyoni, M. A., J. Chem, Phys. 1985, 82, 4867; Pettinger, B. J. Chem. Phys. 1986, 85, 7442) So far in the literature, there are two different theories that can cause Raman scattering. The first theory presented in the literature is the electromagnetic mechanism that results from the stimulated surface plasmons by laser light. The second one is the chemical reaction theory. (Campion, A., Kambhampai, P. Chem. Soc. Rev. 1998, 27, 241; Koskovits, M. Rev. Mod. Phys. 1985, 57, 783) The enhancement of Raman signal depends on the frequency of light, together with properties of metal and substrates on which electromagnetic waves are formed. (Pemberton, J. E. Surface enhanced Raman scattering. In Electro chemical Interfaces. Modern Techniques for In-Situ Characterization; Abruna, H. D., Ed.; VCH Verlag Chemie: Berlin, 1991; p 195)

The development of SERS substrates has been on going and various fabrication techniques are readily present. For example, there are substrates which are composed of nanorod structures. There are also substrates that are composed of clusters of nanoparticles. Electron beam lithography is a tool used for the fabrication of these aforementioned substrates. (U. Huebner, K. Weber a, D. Cialla, R. Haehle, H. Schneidewinda, M. Zeisberger, R. Mattheis, H. -G. Mayer, J. Popp, Microelectronic Engineering, 2012, 98, 444-447) However, the fabrication process that involves electron beam lithography also includes costly steps and consumes a lot of time. There are also SERS substrates made from colloids of silver nanoparticles. (Cotton, T. M., Schultz, S. G., Vanduyne, R. P. J. Am, Chem Soc. 1980, 102, 7960; Cao, Y. W. C., Jin, R. C., Mirkin, C. A. Science, 2002, 297, 1536; Jiang, J., Bosnick, K., Maillard, M., Brus, J. J. Phys. Chem. B 2003, 107, 9964; Moore, B. D., Stevenson, L., Watt, A., Flitsch, S., Turner, N. J., Cassidy, C., Graham, D. Nat Biotechonl. 2004, 22, 1133) But these colloidal substrates also involve a complicated fabrication process. Another problem found in this technique is that the nanoparticles prepared from a chemical reduction process is very sensitive to organic compounds. So when using these SERS nano-colloids, the detection of Raman signal is difficult to achieve due to the sensitivity to organic compounds. The alternative is to use SERS substrates that are fabricated by a physical vapor deposition (PVD) system. These substrates are composed of silver nano-structures. This method produces substrates that are clean and readily available for use right out of a PVD system. The parameters involved in PVD systems are also well studied and controlled. The substrates produced also have high performance. The drawback is the short shelf-time of this kind of substrates because silver is easily oxidized in air. The work from N. Nuntawon, P. Eiamchai, B. Wong-ek, M. Horprathum, K. Limwichean, V. Patthanasettakul, P. Chindaudom, Vacuum, Volume 88, February 2013, Pages 23-27, exemplifies that substrates that are composed of silver nano-structures have shelf-time of 29 days for the detection of methylene blue (MB) at 10⁻⁶ M.

Beside the aforementioned structures of SERS substrates, there are work done to develop 3-dimensional (3D) structured SERS substrates. This means the structure that has a base whose surface is rough in such a way that the roughness has uniform features in nano-scale. This rough base is then coated with a noble metal that clusters in arbitrary and random positions on the rough features. Examples of the 3D-structured SERS substrates include using anodic aluminium oxide (AAO) as the base and depositing silver such that hot spots are formed between the deposited silver nanoparticles. (K. Wong-ek, P. Eiamchai, M. Horprathum, V. Patthanasettakul, P. Limnonthakul, P. Chindaudom, N. Nuntawong, Thin Solid Films, Volume 518, 2010, Issue 23, Pages 7128-7132) Additionally, a hexagonal ZnO base fabricated by vapor-liquid-solid (VLS) method that gets coated by silver is another 3D-structured SERS substrates presented in the literature. (Y. Zhan, D. Ma, K. Zu, and Y. Zhao, ACS Appl. Mater. Interfaces, 2015, 7(10), 5725 5735.) These substrates are based on the fundamental of having noble metal nanoparticles coated on the rough base such that the clusters of nanoparticles have distance between each other in the nanometer range. Metal sheets including, but not limited to aluminium (Al), stainless steel, copper (Cu), zinc (Zn), cobalt (Co), nickel (Ni) and molybdenum (Mo), can be used to make the rough base of 3D-structured SERS substrates given that they can provide good adhesion for the noble metal nanoparticles and that nano-scaled features of roughness can be created on their surface. Each cluster of nanoparticles on the rough base enables for surface plasmon resonance to occur when excited by laser light. Positions that a lot of electromagnetic field is concentrated as a result of strong surface plasmon resonance, are called hot spots. They occur between clusters of the coated noble metal nanoparticles. These hot spots are the cause of the enhancement in Raman signal. Therefore, the performance of 3D-structured SERS substrates depend on the numbers of hot spots that exist on a substrate. Furthermore, the work done by Ruobing Han, Hui Wu, Chunlei Wan, Wei Pan, Scripta Materialia Volume59 (2008), 1047-1050, presents that the positions of hot spots in the 3D-structured SERS substrates can occur arbitrary anywhere on each feature of the roughness.

### SUMMARY OF THE INVENTION

The invention in this application, fabrication process of 3D-structured surface-enhanced Raman spectroscopy (SERS) substrates by using a laser marking machine to create roughness on metal sheets, is aimed to produce SERS substrates that are cheaper to make and involve less complicated fabrication techniques while still give adequate enhancement of Raman signals. It is important to clearly emphasize that there have been previous versions of SERS substrates based on various fabrication techniques. This invention entails the 3D-structured SERS substrates, which comprises: creating roughness on the surface of a metal sheet by a laser marking machine, wherein the specific parameters involved in the settings of a laser marking machine include a laser power in a range of 1-20 W, fill spacing of 0.02-0.15 mm, speed of 1-10,000 mm/s, frequency of 20-200 kHz and repetition rate of 1-50 times; and depositing noble metal particles onto a roughened metal sheet.

A laser marking machine that is normally used to engrave alphabetical letters on various kinds of metal sheets is employed by the inventor of this application to create rough features on metal sheets. In some embodiments, the type of metal sheets for making the rough base is selected from the group consisting essentially of aluminium (Al), stainless steel, copper (Cu), zinc (Zn), cobalt (Co), nickel (Ni) and molybdenum (Mo). This technique of using a laser marking machine is able to yield the roughness on a metal sheet that has features in the range of nanometers to micrometers. In other embodiments, the noble metal is selected from the group comprising silver (Ag), gold (Au), platinum (Pt), copper (Cu) and palladium (Pd). Further still, noble metal nanoparticles are deposited onto the roughened metal sheets by magnetron sputtering, resulting in 3D-structured SERS substrates that are able to enhance Raman signals.

In comparison to different fabrication processes of other SERS substrates, the advantage of this technique is that it involves procedures that are not costly and are rather simple and straightforward with no chemical residue. Plus, the enhancement of the SERS substrates produced from the laser marking technique is still comparable to commercial-grade SERS substrates with the enhancement of more than 1 million times.

### BRIEF DESCRIPTION OF THE DRAWINGS

FIG. 1: Fabrication process of SERS substrates by using a laser marking machine to create nano-to-micro-scaled roughness on the surface of a metal sheet, followed by depositing noble metal nanoparticles on the roughened metal sheet, resulting in a 3D-structured SERS substrate whose noble metal nanoparticles coated on the roughened metal sheet have nano-scaled distances between each other.

FIG. 2: Pictures showing the surface of the Al sheet pre- and post-surface roughening by a laser marking machine. The roughened area is designed to have the dimensions of 5 mm×5 mm.

FIG. 3: Microscopic pictures displaying the surface of the Al sheet pre- and post-roughening by a laser marking machine

FIG. 4: Comparison of Raman spectra when detecting MB at the concentration of 1.0×10⁻⁵ M by using (a) the SERS substrate that is based on a flat, non-roughened Al sheet coated by silver nanoparticles for 20 seconds in a sputtering system; and (b) the SERS substrate that is created from roughening an Al sheet by a laser marking machine with the following settings: laser power of 12 W, fill spacing of 0.02 mm, repetition rate of 5 times, 300 mm/s engraving speed, 30 kHz laser frequency followed by the deposition of silver nanoparticles in sputtering system for 20 seconds FIG. 5: Scanning electron microscopic (SEM) images display different surface conditions of pre- versus post-Al surface roughening with the following: laser power of 12 W, fill spacing of 0.02 mm, repetition of 5 times, engraving speed of 300 mm/s, and laser frequency of 30 kHz, with and without noble metal coating, and at 1K (1000 times) or 1000K (100,000 times) image magnification factors as follows (a) surface of the Al sheet pre-roughening and without Ag coating at the magnification factor of 1K; (b) surface of the Al sheet pre-roughening, without Ag coating at 100K magnification; (c) surface of the Al sheet pre-roughening, with Ag coating for 20 seconds at 1K magnification; (d) surface of the Al sheet pre-roughening, with Ag coating for 20 seconds at 100K magnification; (e) surface of the Al sheet post-roughening by the laser marking machine without Ag coating at 1K magnification; (f) surface of the Al sheet post-roughening by the laser marking machine without Ag coating at 100K magnification; (g) surface of the Al sheet post-roughening by the laser marking machine, Ag coating in the sputtering system for 20 seconds, taken at 1K magnification; (h) surface of the Al sheet post-roughening by the laser marking machine, Ag coating in the sputtering system for 20 seconds, taken at 100K magnification

FIG. 6: Comparison of Raman spectra when detecting MB at the concentration of 1.0×10⁻⁵ mol by the roughened Al sheets created from the following setting: laser power of 12 W, fill spacing of 0.02 mm, repetition of 5 times, engraving speed of 300 mm/s, and laser frequency of 30 kHz, but varying the time of Ag deposition in the sputtering system from (a) 10 seconds; (b) 20 seconds; (c) 30 seconds; (d) 40 seconds; (e) 50 seconds; (f) 60 seconds; (g) 70 seconds

FIG. 7: SEM images with 1K magnification on the left and 100K on the right for each inset of the Al sheet surfaces that have been roughened by the laser marking machine with the following setting: laser power of 12 W, fill spacing of 0.02 mm, repetition of 5 times, engraving speed of 300 mm/s, and laser frequency of 30 kHz, at varying time of Ag deposition in the sputtering system from (a) 10 seconds; (b) 20 seconds; (c) 30 seconds; (d) 40 seconds; (e) 50 seconds; (f) 60 seconds; (g) 70 seconds

FIG. 8: Relationship between the size of silver nanoparticles coated on top of the roughened Al sheet (roughened by the following settings: laser power of 12 W, fill spacing of 0.02 mm, repetition of 5 times, engraving speed of 300 mm/s, and laser frequency of 30 kHz) versus the time of Ag deposition in the sputtering system

FIG. 9: Relationship of the distance between silver nanoparticles versus the time of deposition in the magnetron sputtering system. The deposition was done on the roughened Al sheets of which the roughness was created by the laser marking machine with the following settings: laser power of 12 W, fill spacing of 0.02 mm, repetition of 5 times, engraving speed of 300 mm/s, and laser frequency of 30 kHz.

FIG. 10: Comparison of Raman spectra for the detection of varying concentration of MB from (a) 1×10⁻⁴ M; (b) 1×10⁻⁵ M; (c) 1×10⁻⁶ M; and (d) 1×10⁻⁷ M. All four cases were based on using the roughened Al sheets that were created from the following laser marking machine settings: laser power of 12 W, fill spacing of 0.02 mm, repetition of 5 times, engraving speed of 300 mm/s, and laser frequency of 30 kHz and the deposition time of silver in the sputtering system of 30 seconds.

### DESCRIPTION OF THE PREFERRED EMBODIMENTS

The present disclosure provides for fabrication process of 3D-structured SERS substrates. Particularly, the present disclosure provides for process methods associated laser engraving technology that is able to create rough surface on metal sheets for which the features of the roughness are in nano-scaled range and uniform. Furthermore, the present disclosure provides for noble metal deposition technique in a PVD system in such a way that clusters of noble metal nanoparticles coated on the rough metal sheet base are spaced between each other in nanometer range, allowing for high volumes of hot spots in the 3D-structured SERS substrates.

Metal sheets that do not absorb laser light can be used to make the rough base. Otherwise, such metal sheets cannot be engraved by a laser marking machine. In an exemplary embodiment, the type of metal sheets for making the rough base is selected from the group including, but not limited to aluminium (Al), stainless steel, copper (Cu), zinc (Zn), cobalt (Co), nickel (Ni) and molybdenum (Mo). A typical commercial-grade laser marking machine can create rough surface on the aforementioned metal sheets. In a particular exemplary embodiment, the uniform and nano-scaled rough features can be created on the metal sheets by adjusting the following laser parameters which are given along with their common ranges as follows: power in a range of 1 20 W, fill spacing of 0.02-0.15 mm, speed of 1-10,000 mm/s, frequency of 20-200 kHz and repetition rate of 1-50 times.

Given the property that noble metals have a high volume of electron clouds, they are a key factor that enables 3D-structured SERS substrates to perform well by having great numbers of hot spots. In an exemplary embodiment, the noble metal is selected from the group comprising silver (Ag), gold (Au), platinum (Pt), copper (Cu) and palladium (Pd). A PVD system provides for depositions of noble metal particles in nanometer range. In a particular exemplary embodiment, the parameters and common range of settings in a PVD system that allows for deposition of nanoparticles comprise: pre-deposited chamber pressure of 1−9×10⁻⁶ mbar, argon flow rate during deposition of 5-100 cm⁻³/min, the chamber pressure during deposition regulated between 9×10^{-3 -}9×10⁻² mbar, the DC current of the sputtering system between 0.1-0.5 A, the power of 70-330 W and the time of deposition between 1-300 s.

Comparable to SERS substrates fabricated from other methods in the market, the 3D-structured substrates entailed in this disclosure offer similar applications. For example, SERS substrates can be used in forensic investigation and homeland security to detect trace amount of illicit drugs and explosives. In food safety, SERS substrates can be used to detect the existence of pesticide in fresh produce. The list of applications can extend to include anything that can benefit from trace level detection of bio-molecules and bio-chemical analytes.

The present disclosure is illustrated and described with reference to the following exemplary embodiments by way of examples:

### EXAMPLE I

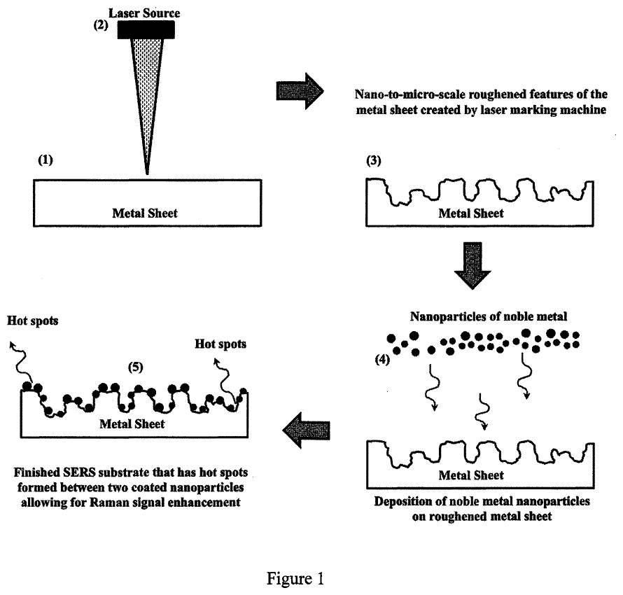

The process flow for making rough surface on a metal sheet by laser engraving technique is depicted in FIG. 1. The numeric labels marked in FIG. 1 stand for: (1) Metal sheets, (2) Laser marking machine, (3) Roughened metal surface, (4) Silver nano-particles coated on roughened metal surface, and (5) Distance between silver nano-particles that are coated on roughened metal surface.

In an exemplary embodiment, aluminium (Al) sheets that are 0.4 mm thick are selected as the metal sheets to be roughened. This is because they are vastly available in the market and the price is reasonable. A 3-step sonication in acetone, isopropanol and deionized (DI) water for 10 minutes each is employed to clean the Al sheets. This is followed by Al sheets drying by a nitrogen gun.

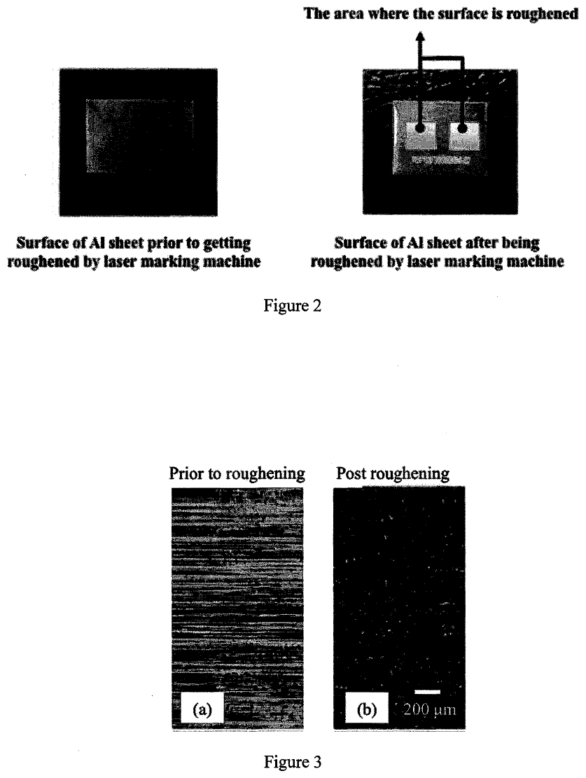

In a particular exemplary embodiment, a programmable laser marking machine is used to create uniform and nano-scaled roughness on the cleaned Al sheets. The programmable laser marking machine can engrave arbitrary structures according to our design. FIG. 2 shows the picture of the cleaned Al sheet before and after surface roughening. The roughened areas are shown in white squares encompassing the area of 5 mm×5 mm in FIG. 2. In FIG. 3, the scanning electron microscopy (SEM) images of the AL sheet before and after surface roughening are shown. The post-roughening image in FIG. 3 depicts uniform and nano-scaled features of roughness. The embodiment as depicted in the post-roughening image in FIG. 3 can be achieved by the following laser marking machine settings: power in a range of 10-15 W, fill spacing of 0.02-0.04 mm, speed of 200-400 mm/s, frequency of 30-50 kHz and repetition rate of 3-8 times. Moreover, the roughened Al sheets undergo a post-roughening cleaning step by a 10-minute sonication in DI water, and are blown dry by a nitrogen gun.

In a further exemplary embodiment, silver is selected as the noble metal to coat on the rough base. Silver is selected because it can enhance Raman signals the most, allowing various spectra to be distinguished more easily. A 3-inch diameter silver target with 99% purity is utilized. Particularly, a magnetron sputtering system is the chosen type of PVD for silver deposition. The deposition of silver nanoparticles occurs in a vacuum chamber of the magnetron sputtering system. The silver nanoparticles coated on the roughened Al sheets must be apart in nanometer range for hot spots that can enhance Raman signals to occur. To achieve this, in a particular exemplary embodiment, the vacuum level of 5×10 mBar is created by rotary and turbomolecular pumps. Furthermore, Ar flow rate of 5-15 cm³/minute is fed into the chamber right before deposition. The chamber pressure is regulated to 1−5×10⁻³ mBar. During deposition, the direct current (DC) and power of the sputtering system are 0.1-0.4 A and 70-150 W, respectively. The deposition time is 30-100 seconds.

### EXAMPLE II

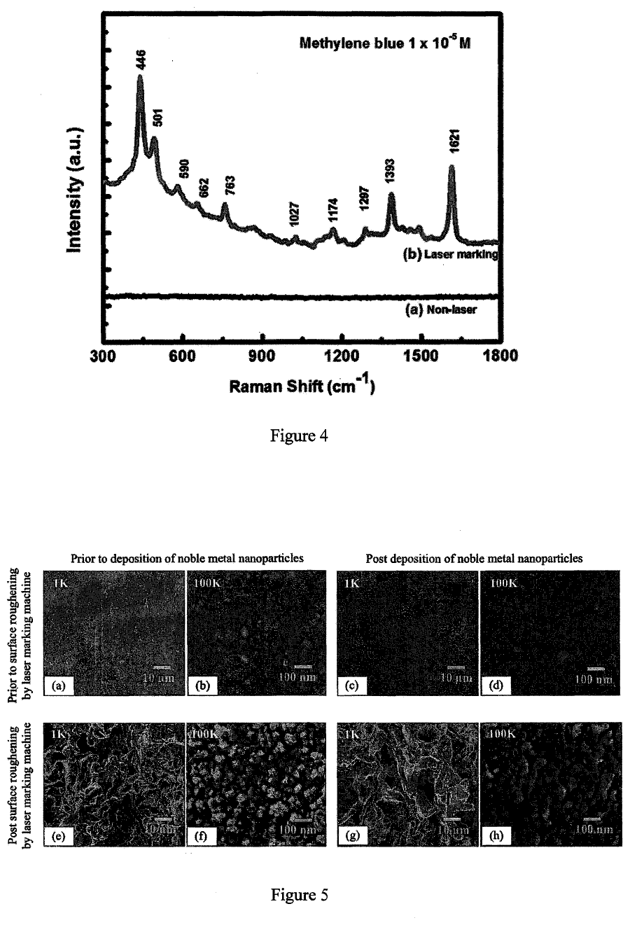

In an exemplary embodiment, a complete 3D-structured SERS substrate is achieved when the surface of an Al sheet that has uniform and nano-scaled roughness is coated by silver nanoparticles whose clusters are apart in nanometer range. The performance of the complete 3D-structured SERS substrates is determined by the detection of methylene blue (MB) at the concentration of 1×10 M. The MB solution is dropped onto the SERS substrates, then placed into the Raman Spectrometer where the laser wavelength is set to 785 nm, the laser power can be adjusted from 0-400 mW, and the measurement time is 10 seconds. In FIG. 4, the result shows the peak signals at 446, 501, 590, 662, 763, 877, 1027, 1174, 1297, 1393 and 1621 cm⁻¹. These peak signals are results of the following bonds δ(C—N—C), δ(C—N—C), N/A, γ(C—CH), N/A, N/A, β(C—H), ν(C—N), N/A, α(C—H) ring and ν(C—C)ring, respectively. (Naujok, R. R., Duevel, R. V., Corn, R. M. Langmuir 1993, 9, 1771; Félidj, N., Aubard, J., Lévi, G., Krenn, J. R., Salerno, M., Schiner, G., Lamprecht, B., Leitner, A., Aussen egg, F. R. Phys. Rev B 2005, 65, 075419; Xiao, G. N., Man, S. Q. Chem. Phys. Letts. 2007, 447, 305) Note that in FIG. 4, there is no peak signal from the substrates whose Al sheets have not been roughened. In FIG. 5, the SEM images show that the surface of the substrates that have not been roughened are quite smooth. So when silver gets deposited for 20 seconds, the result is a thin film of silver and not clusters of silver nanoparticles. So without the clusters of silver nanoparticles, there is no hot spot and Raman signal cannot be enhanced. However, when silver is deposited on the roughened Al substrates, the results are clusters of silver nanoparticles and not a thin film. So with the clusters, hot spots are present and the Raman signal can be enhanced. Additionally, in FIG. 5 the SEM images of the roughened Al substrate prior to silver deposition at the magnification of 1K (1000 times) shows uniform micro-structures of roughness. When the magnification is increased to 100K (100,000 times), uniform nano-structures of rough features can be seen. This exemplifies and emphasizes the importance of the uniform, nano-scaled features of roughness on the surface of a metal base in a 3D-structured SERS substrate. Furthermore, in FIG. 5 when the roughened Al substrates are coated by silver, clusters of silver nanoparticles are formed on the substrates and are apart in nanometer range allowing Raman signal to be enhanced.

### EXAMPLE III

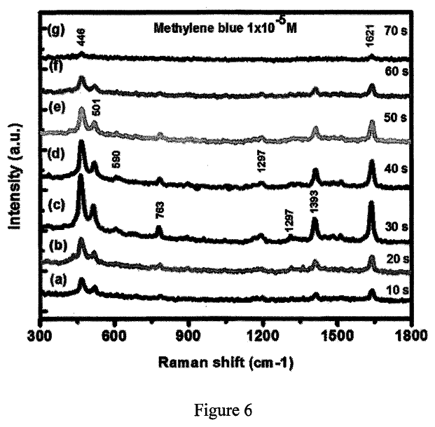

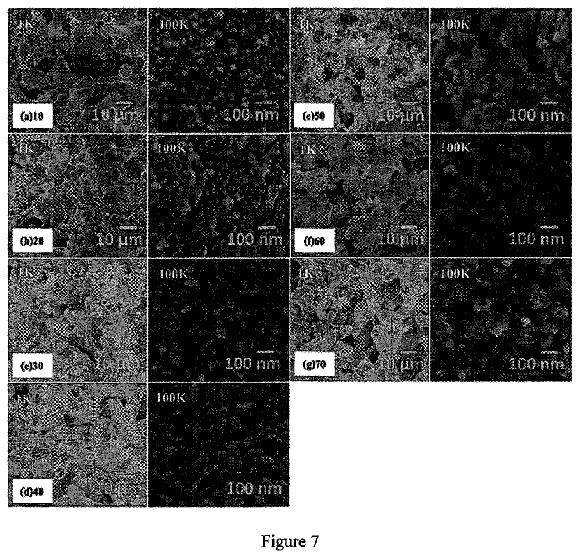

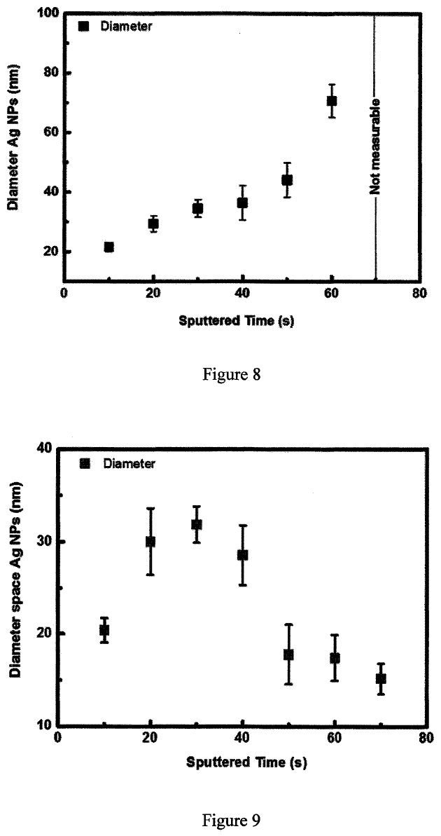

In a further exemplary embodiment, the varying time of silver deposition on the roughened Al sheets results in changing performance of the 3D-structured SERS substrates. FIG. 6 depicts MB detection at 1×10⁻⁵ M of 3D-structured SERS substrates with varying time of silver deposition. The result reveals that the time of deposition affects the size of silver nanoparticles and subsequently the performance of the SERS substrates. In FIG. 6, the deposition times from 10-60 seconds yield the substrates that can detect peak signal of MB at 446, 501, 763, 1393 and 1621 cm⁻¹. The deposition time of 30 seconds gives the highest signal enhancement. The deposition time of 70 seconds results in low signal enhancement with peaks only at 446 and 1621 cm⁻¹. FIG. 7 and FIG.8 show that the size of silver nanoparticles increase with the deposition time. When the deposition reaches 70 seconds, the nanoparticles are very large that the distance between nanoparticles can no longer be measured. As the deposition time increases beyond 70 seconds, the deposited silver starts to become like a thin film so the hot spots disappear. This means as the deposition time of silver increases way beyond 70 seconds, the substrates will lose the ability to enhance Raman signal due to the fact that the hot spots are diminished. In FIG. 9, the deposition time of 30 seconds yields the distance between nanoparticles of 34 nm. This gives the highest signal enhancement among our trials as suggested by the work of H. Tang, G. Meng, Q. Huang, Z. Zhang, Z. Huang and C. Zhu, Avd. Funct. Matter, 2012, 22, 218-224, which states that the distance between nanoparticles of 50 nm results in the greatest Raman enhancement.

### EXAMPLE IV

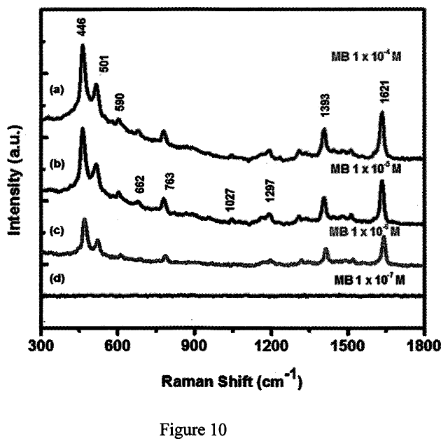

In an exemplary embodiment, 3D-structured SERS substrates are used to detect MB at even lower concentration at 1×10⁻⁶ M. The substrates are fabricated based on the following parameter settings: laser power of 12 W, fill spacing of 0.02 mm, repetition of 5 times, engraving speed of 300 mm/s, and laser frequency of 30 kHz and the deposition time of silver in a sputtering system of 30 seconds. With visible peaks showing at 446, 501, 763, 1393, and 1621 cm⁻¹, FIG. 10 depicts that these SERS substrates can also detect peak Raman signals even from the very low concentration of MB at 1×10⁻⁶ M, which means the Raman signal can be enhanced by 1 million times. The high performance of these SERS substrates result from the uniform nanostructures of roughness created by the laser marking machine which allows silver nanoparticles to coat arbitrarily and randomly. This means the nanoparticles can be on the top and at the sides of each rough feature, or be in between the ridges of the roughness. As a result, a lot of hot spots are created 3-dimensionally on the substrates allowing for greater enhancement of Raman signals.

While the present invention is described herein with reference to exemplified embodiments, it should be understood that the invention is not limited hereto. The described embodiments are to be considered in all respects as illustrative and not restrictive. Those having ordinary skill in the art will recognize additional modifications and embodiments within the scope thereof. Accordingly, such modifications and/or embodiments are considered to be included within the scope of the claims.

1. A fabrication process of 3-dimensional (3D) structured surface-enhanced Raman spectroscopy (SERS) substrates by using a laser marking machine to create roughness on metal sheets on which particles of noble metal are coated, the fabrication process comprising:
creating roughness on the surface of a metal sheet by a laser marking machine; and
depositing noble metal onto a roughened metal sheet,
wherein surface roughness is created using the following parameters: laser power in a range of 1-20 W, fill spacing of 0.02-0.15 mm, speed of 1-10,000 mm/s, frequency of 20-200 kHz and repetition rate of 1-50 times.

2. The fabrication process of 3D-structured SERS substrates according to claim 1, wherein the type of metal sheets for making the rough base is selected from the group consisting of aluminum (Al), stainless steel, copper (Cu), zinc (Zn), cobalt (Co), nickel (Ni) and molybdenum (Mo).

3. The fabrication process of 3D-structured SERS substrates according to claim 2, wherein the metal sheet is Al.

4. The fabrication process of 3D-structured SERS substrates according to claim 1, wherein the laser power setting ranges from 10-15 W.

5. The fabrication process of 3D-structured SERS substrates according to claim 1, wherein the laser fill spacing setting ranges from 0.02-0.04 mm.

6. The fabrication process of 3D-structured SERS substrates according to claim 1, wherein the laser speed, frequency and repetition rate settings are 200-400 mm/s, 30-50 kHz and 3-8 times, respectively.

7. The fabrication process of 3D-structured SERS substrates according to claim 1, wherein the process produces a roughened area that encompasses a squared shape of dimensions 5 mm×5 mm.

8. The fabrication process of 3D-structured SERS substrates according to claim 1, wherein the noble metal is selected from the group of silver (Ag) or gold (Au) or platinum (Pt) or copper (Cu) or palladium (Pd).

9. The fabrication process of 3D-structured SERS substrates according to claim 1, wherein the noble metal is silver (Ag).

10. The fabrication process of 3D-structured SERS substrates according to claim 1, wherein the particles of noble metal comprise particles that are sized in nanometer range.

11. The fabrication process of 3D-structured SERS substrates according to claim 1, wherein depositing is carried out in a vacuum chamber of a physical vapor deposition (PVD) system.

12. The fabrication process of 3D-structured SERS substrates according to claim 11, wherein the PVD system is magnetron sputtering,

13. The fabrication process of 3D-structured SERS substrates according to claim 9, wherein depositing uses a silver sputtering target which has the purity greater than 99% and the a diameter of 3 inches.

14. The fabrication process of 3D-structured SERS substrates according to claim 12, wherein the vacuum level in a magnetron sputtering system is reached by utilizing a rotary pump and a turbo-molecular pump.

15. The fabrication process of 3D-structured SERS substrates according to claim 1, wherein the depositing step is performed in vacuum with the pre-deposited chamber pressure of 1−9×10 mbar, the rate of argon flow during the deposition is 5-100 cm⁻³/min, the chamber pressure during deposition is regulated between 9×10⁻³-9×10⁻² mbar, the DC current of the sputtering system is 0.1-0.5 A, the power is 70-330 W and the time of deposition is 1-300 s.

16. The fabrication process of 3D-structured SERS substrates according to claim 15, wherein the flow rate of argon during the depositing step is 5-15 cm⁻³/min.

17. The fabrication process of 3D-structured SERS substrates according to claim 15, wherein the pressure inside the chamber during the depositing step is 1−5×10⁻³ mbar.

18. The fabrication process of 3D-structured SERS substrates according to claim 15, wherein the DC current and power of the sputtering system during the depositing step are 0.1-0.4 A and 70-150 W, respectively.

19. The fabrication process of 3D-structured SERS substrates according to claim 15, wherein the deposition time is 30-100 s.
